(19) United States
(12) Patent Application Publication
(10) Pub. No.: US 2026/0136871 A1
(43) Pub. Date: May 14, 2026

(54) Display Panel Manufacturing Apparatus

(71) Applicant: LG Display Co., Ltd., Seoul (KR)

(72) Inventors: Youngsuk Hwang, Anyang-si (KR); Doyoung Kwak, Hanam-si (KR); Hansaem Kang, Goyang-si (KR); Bongseok Choi, Gimpo-si (KR)

(21) Appl. No.: 19/343,512

(22) Filed: Sep. 29, 2025

(30) Foreign Application Priority Data
Nov. 12, 2024 (KR) 10-2024-0160236

(51) Int. Cl. H01L 21/67; H10H 29/02

(52) U.S. Cl. CPC H10P 72/0438; H10H 29/02

(57) ABSTRACT

The present disclosure relates to a display panel manufacturing apparatus that prevents light-emitting elements from being damaged when detached from a donor member during a transfer process. To realize this, the display panel manufacturing apparatus of the present disclosure can pick up a plurality of light-emitting elements, without any damages to them, through a transfer member from a donor member in which the plurality of light-emitting elements are disposed to be connected to each other by a tether structure, by configuring the tether to be easily broken, and forming a plurality of protrusions on the substrate to support the light-emitting elements in the course of the picking up the plurality of light-emitting elements.

### CROSS-REFERENCE TO RELATED APPLICATION

This application claims priority to Republic of Korea Patent Application No. 10-2024-0160236 filed on Nov. 12, 2024, which is incorporated by reference in its entirety.

### BACKGROUND

### Field

This disclosure relates to a display panel manufacturing apparatus, and more specifically, to a display panel manufacturing apparatus that transfers a light-emitting element (or LED) onto a display panel.

### Description of the Related Art

Recently, display devices including a light-emitting diode (LED) (hereinafter, referred to as a “light-emitting element”) are attracting attention as next-generation display devices. Since the light-emitting element is not configured with organic materials but inorganic materials, it can light up faster than the liquid crystal display device or the organic light-emitting display device, have excellent light-emitting efficiency, and display high-brightness images.

These light-emitting elements are connected in a tether structure on a donor member as a package unit in the transfer process. The light-emitting elements connected in a tether structure are detached from the donor member as a package unit when the tether structure is broken, and are transferred onto the display panel through a transfer member.

However, if all the tethers are not broken simultaneously when the light-emitting elements are detached from the donor member, this may lead to a problematic situation where the side portion of the package or the light-emitting element is damaged, or misalignment occurs between the transfer member and the light-emitting elements.

### SUMMARY

In view of the above, in order to address the above-mentioned drawback, embodiments of the present disclosure are directed to a display panel manufacturing apparatus that prevents light-emitting elements from being damaged when detached from a donor member in a transfer process.

An object to be accomplished according to one or more embodiments of the present disclosure is to provide a display panel manufacturing apparatus which can prevent damage to a light-emitting element package without the occurrence of misalignment between a transfer member and light-emitting elements by enabling the light-emitting elements to be easily detached from a donor member without being damaged during a transfer process.

The objects of the present invention are not limited to the one described above, and other objects and advantages of the present invention which are not mentioned can be understood from the following description, and will be more clearly understood from the embodiments of the present invention. Furthermore, it will be readily appreciated that the objects and advantages of the present disclosure can be realized by the means presented in the claims, and combinations thereof.

A display panel manufacturing apparatus according to one or more embodiments of the present disclosure can pick up a plurality of light-emitting elements, without any damages to them, through a transfer member from a donor member in which the plurality of light-emitting elements are disposed to be connected to each other by a tether structure, by configuring the tether to be easily broken and forming a plurality of protrusions on the substrate to support the light-emitting elements in the course of the picking up.

According to one or more embodiments of the present disclosure, it is possible to produce an effect of preventing the damage to light-emitting elements by limiting the movement displacement of the light-emitting elements with the protrusion structure when the transfer member picks up the light-emitting elements during the transfer process of light-emitting elements.

In addition, according to one or more embodiments of the present disclosure, it is possible to produce an effect of improving the transfer precision and thus preventing panel defects by preventing the damage to the light-emitting elements during the transfer process.

In addition, according to one or more embodiments of the present disclosure, it is possible to realize the improvement of the quality of a display device by preventing the damage to the light-emitting elements or the panel defects.

In addition, according to one or more embodiments of the present disclosure, the reduction in the lifespan of the display panel can be prevented by decreasing defects in the display panel.

In addition, according to one or more embodiments of the present disclosure, it is possible to produce an effect of providing a long-life, low-power display device by preventing panel defects and thereby allowing the display panel to operate without failure.

The present disclosure may have other effects besides the aforementioned ones, which are clearly recognizable to a person skilled in the art from the description below.

In addition to the effects described above, specific effects of the present invention will be described below together with specific details for practicing the invention.

### BRIEF DESCRIPTION OF THE DRAWINGS

FIG. 1 is a view schematically showing the overall configuration of a display panel manufacturing apparatus according to one or more embodiments of the present disclosure.

FIG. 2 is a cross-sectional view representing a configuration example of a donor member shown in FIG. 1.

FIG. 3 is a plan view representing a planar configuration example for the transfer member shown in FIG. 1.

FIG. 4 is a side view representing a side configuration example for the transfer member shown in FIG. 1.

FIG. 5 is a view representing an example of a donor member and a transfer member corresponding to each other according to one or more embodiments of the present disclosure.

FIG. 6 is a view representing an example in which a transfer member adheres to a donor member to apply a pressure thereto according to one or more embodiments of the present disclosure.

FIG. 7 is a view representing an example in which a tether is damaged when a transfer member is separated from a donor member according to one or more embodiments of the present disclosure.

FIG. 8 is a view representing a configuration example of a light-emitting element package disposed on a donor member according to one or more embodiments of the present disclosure.

FIG. 9 is a view representing an example in which sub-elements disposed on a donor member are covered by an encapsulation layer according to one or more embodiments of the present disclosure.

FIG. 10 is a view representing an example in which sub-elements are picked up from a donor member according to one or more embodiments of the present disclosure.

FIG. 11 is a view representing a configuration example of a transfer member according to one or more embodiments of the present disclosure.

FIG. 12 is a view representing an example in which an encapsulation layer covering sub-elements is picked up by a transfer member according to one or more embodiments of the present disclosure.

FIGS. 13 to 16 are views representing processes for picking up and transferring sub-elements from a donor member according to one or more embodiments of the present disclosure.

FIG. 17 is a plan view showing various embodiments of protrusions formed on a substrate in a donor member according to one or more embodiments of the present disclosure.

### DETAILED DESCRIPTION

Advantages and features of the present disclosure, and a method of achieving the advantages and features will become apparent when referring to the following embodiments described later in detail together with the accompanying drawings. However, the present disclosure is not limited to the embodiments as disclosed below, but may be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology may unnecessarily obscure the gist of the present disclosure, the detailed description thereof will be omitted. When the terms “comprise”, “include,” “have,” “configure,” and the like are used in this disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “under”, and “next to”, one or more other elements may be interposed between the two elements unless the term “just”, “directly”, or “close” is used.

In describing a temporal relationship, for example, when the temporal order is described as “after”, “subsequent”, “next”, “before”, or the like, the case which is not continuous may also be included unless the term “just” or “directly” is used.

It will be understood that, although the terms “first”, “second”, etc. may be used herein to describe various elements, these elements should not be limited by these terms. These terms are only used to distinguish one element from another element. So, a first element referred to in the following description may represent a second element, without departing from the scope of the technical idea of the present disclosure.

In describing components herein, terms such as A, B, (a), or (b) may be used. These terms are only intended to distinguish one component from another, and do not limit the nature, order, sequence, or number of the components. When a component is described as being “connected to,” “coupled to,” “access to,” “attached to”, “adhere”, or “stick” to another component, such component may be directly connected to, coupled to, contact with, or attached to the other component, and, however, it should be understood that they may be indirectly connected to, coupled to, access to, attached, adhere, or stick to each other with still another component interposed therebetween, unless explicitly stated to the contrary.

The expression “at least one” should be understood to include any combination of one or more of the associated components. For example, the meaning of “at least one of the first, second, and third components” may include not only the first, second, or third component, but also any combination of two or more of the first, second, and third components.

In this disclosure, a “device” may include a display device, such as a liquid crystal module (LCM), an organic light-emitting display module (OLED module), or an inorganic light-emitting display module, which includes a display panel and a driver for driving the display panel. And, it may also include a set electronic apparatus or a set device (or set apparatus), such as a notebook computer, a television set, a computer monitor, a vehicle or automotive apparatus, or a mobile electronic apparatus such as a smart phone or an electronic pad, which is a complete product or final product including an LCM, an OLED module, an inorganic light-emitting display module, or the like.

Accordingly, the device in the present disclosure may include a display device itself, such as an LCM, an OLED module, an inorganic light-emitting display module, or the like, and even a set device, which is an applied product or end-user device including an LCM, an OLED module, an inorganic light-emitting display module, or the like.

And, in some embodiments, an LCM or an OLED module configured with a display panel, a driver, and the like may be referred to as a “display device,” and an electronic device, which is as a complete product and includes an LCM or an OLED module, may be differentially referred to as a “set device.” For example, the display device may include a display panel of a liquid crystal display (LCD) or an organic light emitting display (OLED), and a source PCB which is a controller for driving the display panel. The set device may further include a set PCB, which is a set controller that is electrically connected to the source PCB and drives the entire set device.

The display panel used in one or more embodiments of the present disclosure may be any type of display panel, such as a liquid crystal display panel, an organic light emitting diode (OLED) display panel, an electroluminescent display panel, or the like. However, this is not exhaustive. For example, the display panel according to one or more embodiments of the present disclosure may be a display panel that can generate sound by being vibrated by a vibration device. The display panel applied to the display device according to one or more embodiments of the present disclosure is not limited to the shape or size of the display panel.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, embodiments of the present disclosure will be described with reference to the accompanying drawings and examples. The scale of the components depicted in the drawings is different from the actual scale for convenience of explanation, and is not limited to the scale to which the drawings are made.

Hereinafter, as one or more embodiments of the present disclosure, a display device using a micro LED (Light Emitting Diode) as a light-emitting element will be described.

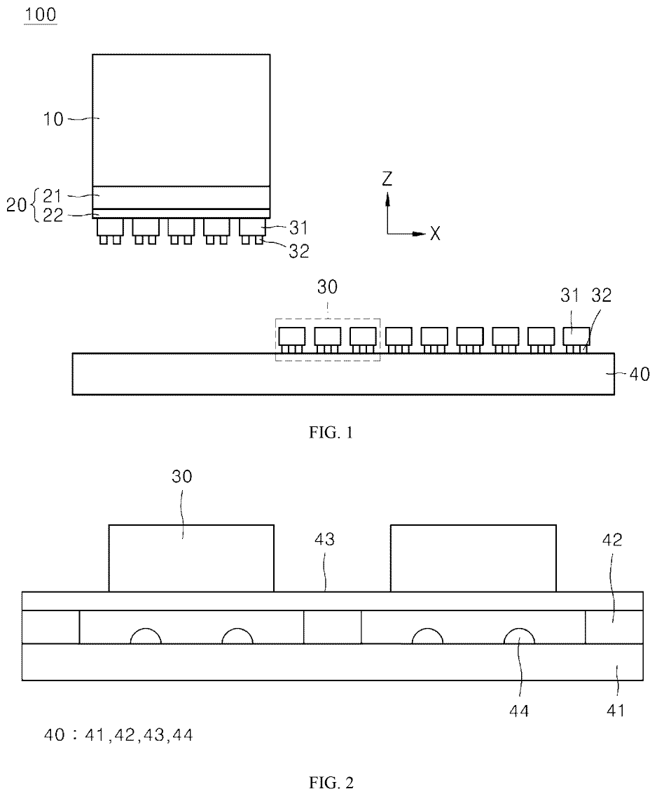

FIG. 1 is a view schematically showing the overall configuration of a display panel manufacturing apparatus according to one or more embodiments of the present disclosure. FIG. 2 is a cross-sectional view representing a configuration example of a donor member shown in FIG. 1.

Referring to FIGS. 1 and 2, a display panel manufacturing apparatus 100 according to one or more embodiments of the present disclosure may include a transport member 10, a transfer member 20, a light-emitting element package 30, and a donor member 40.

The transport member 10 may be used to transport the transfer member 20. Here, although not shown in the drawings, the transport member 10 may include a transport head, a head chuck, and a laser transmitting part. The head chuck may attach or detach the transfer member 20 to or from itself. The laser transmitting part may transmit laser, and may heat and press the light-emitting element 31 during the bonding process of the light-emitting element 31.

The transfer member 20 may pick up a plurality of light-emitting elements 31 from the donor member 40, and transfer them onto a display panel. The transfer member 20 may be formed of a material that transmits laser.

The light-emitting element 31 may have a shape of a chip including an organic material or an inorganic material. Therefore, the light-emitting element 31 may be referred to as an ‘LED chip’, a ‘light-emitting chip’, or an ‘element chip’.

A bonding electrode 32 may be disposed on one surface of the light-emitting element 31. The bonding electrode 32 may be a bonding material for a press-melt bonding using laser beam. Here, the press-melt bonding refers to a state in which the bonding electrode 32 is heated and melted to melt-mix the light-emitting element 31 with an anode pad electrode (not shown) and a cathode pad electrode (not shown) of a substrate, and then cooled and solidified after the cease of the laser supply. Since the conductivity by the anode pad electrode and the cathode pad electrode with the light-emitting element 31 is maintained as they are cooled and solidified from the melt-mixed state, the anode pad electrode and the cathode pad electrode can be respectively electrically and physically connected with the light-emitting element 31. Thus, the bonding electrode 32 may be disposed on one surface of the light-emitting element 31.

The bonding electrode 32 may include, for example, gold (Au), a gold and tin compound (AuSn), a palladium and indium compound (PdIn), an indium and tin compound (InSn), a tin and nickel compound (NiSn), a gold compound (Au—Au), an indium and silver compound (AgIn), a silver and tin compound (AgSn), aluminum (Al), silver (Ag), a carbon nanotube (CNT), or the like. These may be used individually or in combination of two or more. Depending on the kind of the bonding electrode 32, the bonding electrode 32 may be formed by being deposited on the pad electrode, or may be formed on the pad electrode through various methods such as screen printing.

Additionally, each of the light-emitting elements 31 may be moved onto the anode pad electrode and the cathode pad electrode of the substrate by the transfer member 20. In this regard, the substrate may be a sapphire substrate, but the embodiments of the present disclosure are not limited thereto.

The light-emitting element package 30 may provide a plurality of light-emitting elements 31 bundled into a package. A single light-emitting element package 30 may include, for example, first to fourth sub-elements that emit light of different colors.

The donor member 40 may be disposed such that a plurality of light-emitting elements 31 are connected to each other by a tether structure. The donor member 40 may be, for example, a CoD (Chip on Donor) substrate on which a plurality of LED chips are arranged.

The tether structure may include a plurality of anchors 42 spaced apart at regular intervals on the substrate 41, and a plate-shaped tether 43 disposed on the plurality of anchors 42.

A plurality of light-emitting element packages 30 may be disposed to be arranged at regular intervals on the donor member 40. A single light-emitting element package 30 may include a plurality of light-emitting elements 31.

The light-emitting element 31 may include a micro LED. The micro LED may be formed into a size of approximately 10 to 100 μm. Although not shown in the drawings, the micro LED may be fabricated by forming a buffer layer on a substrate and growing a GaN thin film on the buffer layer. In this regard, sapphire, silicon (Si), GaN, silicon carbide (SiC), gallium arsenide (GaAs), zinc oxide (ZnO), or the like may be used as the substrate for growing the GaN thin film. In one or more embodiments of the present disclosure, for example, a sapphire substrate may be used as the substrate for growing the GaN thin film.

Additionally, in the case where the substrate for growing the GaN thin film is made of other material instead of the GaN substrate, AlN, GaN, or the like may be used in the buffer layer which is used to prevent quality degradation caused by the lattice mismatch that occurs when directly growing an n-type GaN layer, which is an epi layer, on such a substrate.

The n-type GaN layer may be formed by growing a GaN layer not doped with any impurities and then doping the upper portion of an undoped thin film layer with an n-type impurity, such as Si. Additionally, a p-type GaN layer may be formed by growing an undoped GaN thin film and then doping it with p-type impurities such as Mg, Zn, or Be.

Each of the plurality of light-emitting elements 31 may be detached from the donor member 40 as one or more sub-elements, and transferred onto the display panel through the transfer member 20.

Each of the plurality of light-emitting elements 31 may be disposed on the tether 43 between the plurality of anchors 42.

The tether 43 may be a structure that binds and connects a plurality of light-emitting elements 31. The anchor 42 may be a structure that acts as a pillar or support to support the tether 43 when binding a plurality of light-emitting elements 31 with the use of the tether 43.

The anchor 42 may be comprised of a first material, and the tether 43 may be comprised of a second material. The first material and the second material may independently be an organic material (benzocyclobutene, phenol formaldehyde resin, epoxy resin, polyisoprene rubber, or a combination thereof), and the first material and the second material may be an inorganic material (e.g., silicon oxide, silicon nitride, silicon oxynitride, or a combination thereof), another thermally modified material (e.g., a low temperature material), a high temperature melting material, a photoresist material, or a combination thereof.

The transfer member 20 may include a base layer 21 and a stamp layer 22 disposed on one surface of the base layer 21.

The base layer 21 may be comprised of, for example, glass or plastic. If the base layer 21 includes thin glass, the glass may be ultra-thin tempered glass. Alternatively, the base layer 21 may be comprised of polyethylene terephthalate (PET), polyurethane (PU), polyimide (PI), polycarbonate (PC), polyethylene (PE), polypropylene (PP), polysulfone (PSF), polymethyl methacrylate (PMMA), triacetyl cellulose (TAC), cycloolefin polymer (COP), or the like.

On the surface of the stamp layer 22, a material having adhesion or stickiness may be applied. The material having adhesion or stickiness may include, for example, OCA (Optical Clear Adhesive), PSA (Pressure Sensitive Adhesive), and the like, and the material having stickiness may include, for example, acrylic, urethane, and silicone-based sticky materials. The stamp layer 22 may be formed with a thickness smaller than the thickness of the base layer 21. The stamp layer 22 may be disposed on one surface of the base layer 21 to be adhered or stuck to a plurality of light-emitting elements 31.

In addition, the display panel manufacturing apparatus 100 according to one or more embodiments of the present disclosure may further include a controller and a heating member, although not shown in the drawings.

The controller may control other components. For example, the controller may move the transport member 10 to a desired position along a first direction (e.g., X), a second direction (e.g., Y), and a third direction (e.g., Z). As another example, the controller may control the suction and discharge of the head chuck. In the following, for the convenience of explanation, the operation of components may be described without mentioning the controller, for example, as follow: the transport member 10 moves, or the head chuck of the transport member 10 sucks or discharges the transfer member 20.

The heating member may provide heat for the bonding of the light-emitting element 31. For example, the heating member may provide laser irradiation to the light-emitting element 31 through the laser transmitting part and the transfer member 20. Thereby, the press-melt bonding of the light-emitting element 31 can be achieved.

A plurality of protrusions 44 may be formed on the substrate 41 between a plurality of anchors 42. The substrate 41 may be, for example, a plastic substrate, a glass substrate, a sapphire substrate, or other substrates with no circuit. However, the embodiments of the present disclosure are not limited thereto.

Each of the plurality of protrusions 44 may have one or more shapes among a hemisphere shape, a rectangular parallelepiped shape, a hexahedron shape, a cylinder shape, and a hemispherical columnar shape. The plurality of protrusions 44 may be formed by a wet-etching process.

Each of the plurality of protrusions 44 may have a height smaller than the height of the plurality of anchors 42. In this regard, if the plurality of protrusions 44 have the same height as the plurality of anchors 42, the plurality of protrusions 44 come into contact with the tether 43 located above them, so the tether 43 has no space beneath to move downward, thus having no elasticity. That is, there needs to be a certain space below the tether 43 on which the plurality of light-emitting elements 31 are disposed, so that the tether 43 can have elasticity due to the space, and be pushed into the space beneath by the pressure applied by the transfer member 20, resulting its breakage when exceeding a certain amount of elasticity.

Each of the plurality of protrusions 44 may have a thickness smaller than the thickness of the plurality of anchors 42. Alternatively, each of the plurality of protrusions 44 may have a thickness greater than the thickness of the plurality of anchors 42.

The plurality of protrusions 44 can prevent the light-emitting element 31 from falling onto the bottom of the substrate 41 when the tether 43 is broken at both sides of the light-emitting element 31 by the pressure applied by the transfer member 20.

Accordingly, these plurality of protrusions 44 have the effect of limiting the movement of the light-emitting element package 30 or the plurality of light-emitting elements 31 that occurs during the transfer process, thereby preventing damage to the package or the light-emitting elements and improving transfer accuracy.

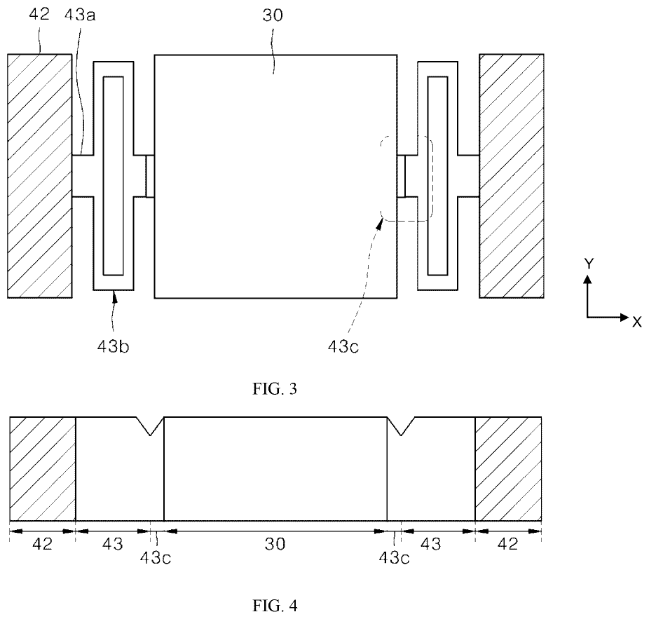

FIG. 3 is a plan view representing a planar configuration example for the transfer member shown in FIG. 1. FIG. 4 is a side view representing a side configuration example for the transfer member shown in FIG. 1.

Referring to FIGS. 3 and 4, the tether 43 between the anchor 42 and the light-emitting element package 30 may include a straight surface 43a in a plate shape, a through-hole surface 43b in which a through-hole is formed, and a trench surface 43c in which a trench is formed in the shape of a ditch or trench.

Here, the light-emitting element package 30 may be one light-emitting element 31, one sub-element, or one light-emitting element package 30.

The width of the through-hole surface 43b may be equal to the width of the light-emitting element package 30, and be greater than the width of the straight surface 43a. In this example, the width is the size measured along the Y direction as shown in FIG. 3.

The width of the straight surface 43a may be equal to the width of the trench surface 43c. Alternatively, the width of the straight surface 43a may be different from the width of the trench surface 43c.

In the case where the light-emitting element package 30 is a plurality of light-emitting elements 31, the width of each light-emitting element 31 may be equal to the width of each anchor 42, and be equal to the width of the through-hole surface 43b.

Alternatively, the width of each light-emitting element 31 may be different from the width of each anchor 42, and be different from the width of the through-hole surface 43b.

On the upper surface of the tether 43, an adhesive material or a sticky material may be applied, and the tether 43 may be adhered or stuck to each of the plurality of light-emitting elements 31 by the adhesive or sticky material.

Here, the material having adhesion or stickiness may include, for example, OCA (Optical Clear Adhesive), PSA (Pressure Sensitive Adhesive), and the like, and the material having stickiness may include, for example, acrylic, urethane, and silicone-based adhesive materials.

A plurality of light-emitting elements 31 may be arranged at regular intervals on the tether of the donor member 40.

When the transfer member 20 picks up a plurality of light-emitting elements 31 from the donor member 40, it can be adhered or stuck to the plurality of light-emitting elements 31 by the adhesive material or the sticky material on the stamp layer.

In a state where the stamp layer of the transfer member 20 adheres or sticks to the plurality of light-emitting elements 31 arranged on the tether 43 of the donor member 40, the tether 43 may be broken at both sides of each light-emitting element 31 by the pressing pressure of the transfer member 20.

The stickiness or adhesion between the transfer member 20 and the plurality of light-emitting elements 31 may be greater than the stickiness or adhesion between the donor member 40 and the plurality of light-emitting elements 31.

Therefore, when the transfer member 20 picks up a plurality of light-emitting elements 31 from the donor member 40, the tether 43 between the plurality of anchors 42 and the plurality of light-emitting elements 31 may be damaged or broken.

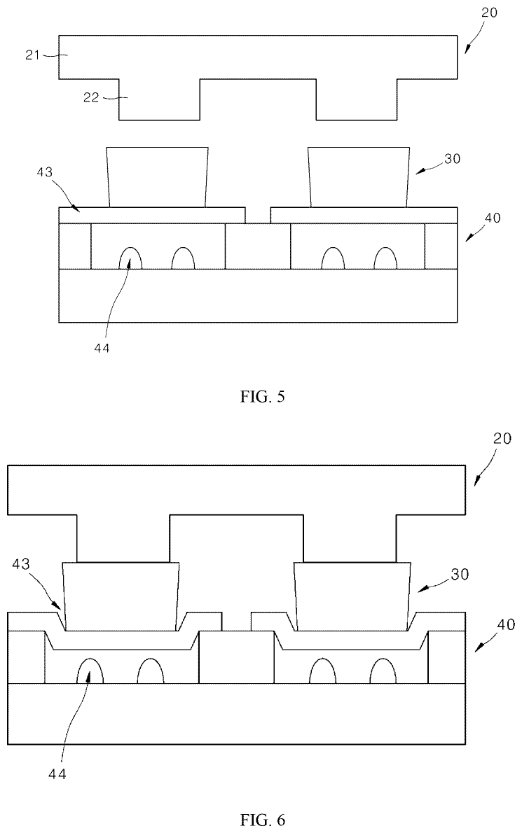

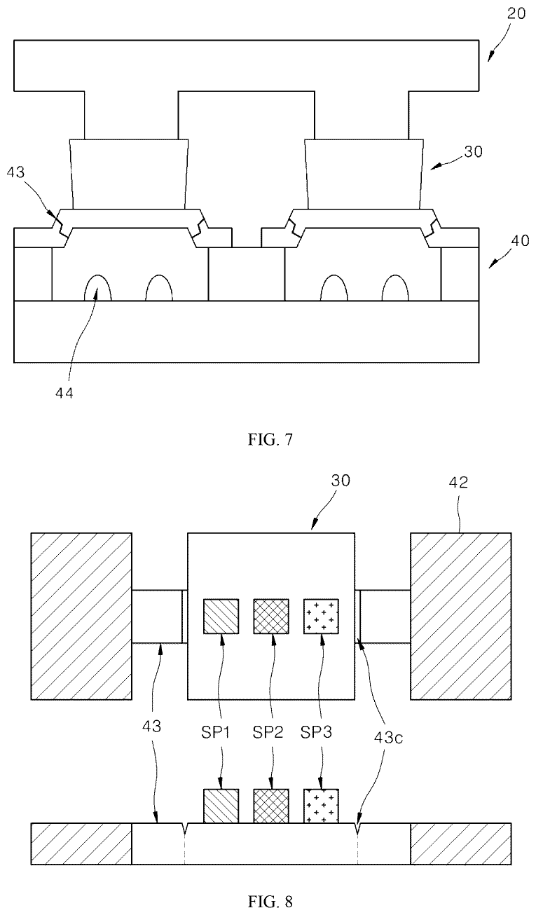

FIG. 5 is a view representing an example of a donor member and a transfer member corresponding to each other according to one or more embodiments of the present disclosure. FIG. 6 is a view representing an example in which a transfer member adheres to a donor member to apply a pressure thereto according to one or more embodiments of the present disclosure. FIG. 7 is a view representing an example in which a tether is damaged when a transfer member is separated from a donor member according to one or more embodiments of the present disclosure.

Referring to FIG. 5, in the donor member 40 according to one or more embodiments of the present disclosure, a plurality of light-emitting element packages 30 are disposed on the tether 43 at regular intervals.

The transfer member 20 may move toward the donor member 40 to correspond to the donor member 40 in order to pick up the plurality of light-emitting element packages 30 from the donor member 40 in which the plurality of light-emitting element packages 30 are disposed at regular intervals.

The transfer member 20 may be positioned so that each stamp layer 22 corresponds to each of the plurality of light-emitting element packages 30. The stamp layer 22 may have a spring structure, although not shown in the drawings. Therefore, the stamp layer 22 may have elasticity.

On the surface of the stamp layer 22 facing the plurality of light-emitting element packages 30, the adhesive material or sticky material may be applied. Accordingly, the stamp layer 22 can be adhered or stuck to the plurality of light-emitting element packages 30 by the adhesive material or sticky material, thereby picking up the plurality of light-emitting element packages 30.

Although not shown, a protective film may be attached to one surface of the stamp layer 22. The protective film may be comprised of, for example, glass or plastic. If the protective film includes thin glass, the glass may be ultra-thin tempered glass.

Before the transfer member 20 picks up the plurality of light-emitting element packages 30 through the stamp layer 22, the protective film attached to the one surface of the stamp layer 22 can be peeled off from the stamp layer 22.

The transfer member 20 may be transferred above the donor member 40 by the transport member 10. The transport member 10 may move to pick up and transport the transfer member 20 disposed on a support member (not shown). The support member serves to support a plurality of transfer members 20. The plurality of transfer members 20 may be arranged and disposed on the support member.

The protective film may be removed in a state where the transfer member 20 is held by the transport member 10, and the transport member 10 may pick up the plurality of light-emitting element packages 30 from the donor member 40 using the transfer member 20.

In this regard, first, the donor member 40 is prepared, in which the plurality of light-emitting element packages 30 are aligned. On the surface of the donor member 40, the material having stickiness may be applied. By the material having stickiness, the plurality of light-emitting element packages 30 may stick to the donor member 40.

The transport member 10 transports the transfer member 20 to the donor member 40 to make the plurality of light-emitting element packages 30 adhered to one surface of the transfer member 20, as shown in FIG. 6. In FIGS. 6 and 7, the notations for the same components as in FIG. 5 e.g., 21 and 22 are omitted.

The transfer member 20 applies pressure to the donor member 40 by the transport member 10.

Accordingly, the tether 43 of the donor member 40 is bent due to the pressure transmitted through the light-emitting element package 30 adhered to the stamp layer of the transfer member 20.

After this, the transfer member 20 is moved in an upward direction (i.e., Z-axis direction) to detach the plurality of light-emitting element packages 30 from the donor member 40.

In order to detach the light-emitting element packages 30 from the donor member 40 with the use of the transfer member 20, the stickiness or adhesion between the stamp layer 22 of the transfer member 20 and the light emitting device package 30 needs to be greater than the stickiness or adhesion between the donor member 40 and the light emitting device package 30.

In addition, the transport member 10 needs to apply to the transfer member 20 a tensile force greater than the stickiness or adhesion between the donor member 40 and the light-emitting element package 30 in an upward direction (i.e., Z-axis direction).

Therefore, when the transfer member 20 moves in an upward direction from the donor member 40, the tether 43 adhered to the light-emitting element package 30 can be broken or damaged at both sides of the light-emitting element package 30, as shown in FIG. 7.

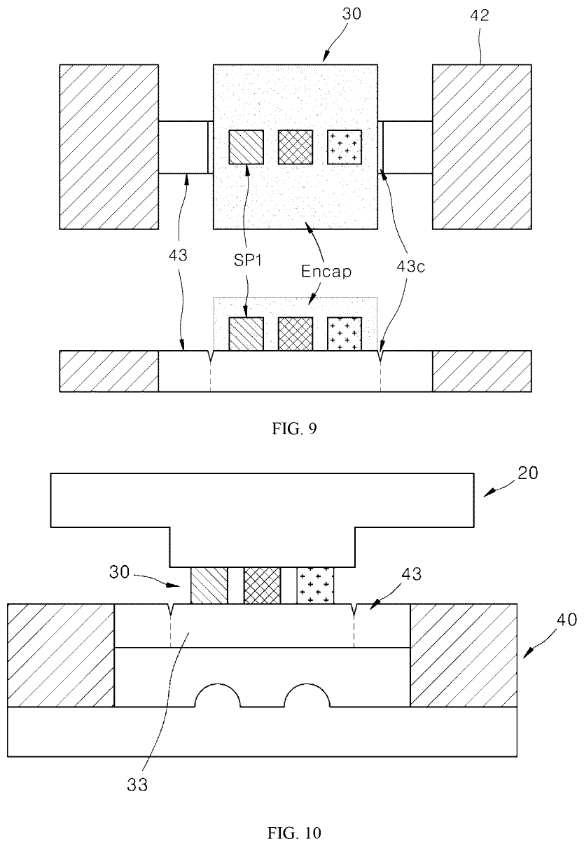

FIG. 8 is a view representing a configuration example of a light-emitting element package disposed on a donor member according to one or more embodiments of the present disclosure. FIG. 9 is a view representing an example in which sub-elements disposed on a donor member are covered by a encapsulation layer according to one or more embodiments of the present disclosure. FIG. 10 is a view representing an example in which sub-elements are picked up from a donor member according to one or more embodiments of the present disclosure.

Referring to FIGS. 8 and 9, each of the light-emitting element packages 30 disposed on the donor member 40 according to one or more embodiments of the present disclosure may include a first sub-element SP1 emitting light of a first color; a second sub-element SP2 emitting light of a second color; and a third sub-element SP3 emitting light of a third color, all of which are adhered or stuck to the tether 43 by an adhesive material or a sticky material on the tether 43. Each of the light-emitting element packages 30 may further include a fourth sub-element emitting light of a fourth color.

For example, if the first color is red, the second color may be green, the third color may be blue, and the fourth color may be white. The first color, second color, third color and fourth color may be respectively any one of red (R), green (G), blue (B) and white (W).

In each of the plurality of light-emitting element packages 30, one or more sub-elements SP may be detached from the donor member 40 and transferred onto the display panel through the transfer member 20.

In each of the light-emitting element packages 30, the first sub-element SP1, the second sub-element SP2, and the third sub-element SP3 may be covered by an encapsulation layer Encap. The encapsulation layer Encap can protect the sub-elements SP1 to SP3 from, for example, moisture penetration.

Referring to FIG. 10, the light-emitting element package 30 according to one or more embodiments of the present disclosure may have one or more sub-elements SP1 to SP3 disposed on a package lower substrate 33.

For example, the first sub-element SP1, the second sub-element SP2, and the third sub-element SP3 may be disposed on the package lower substrate 33 to which an adhesive material or a sticky material is applied.

Accordingly, the transfer member 20 can pick up the first sub-element SP1, the second sub-element SP2, and the third sub-element SP3, all of which constitute the light-emitting element package 30, from the donor member 40 together with the package lower substrate 33, and transfer them onto the display panel.

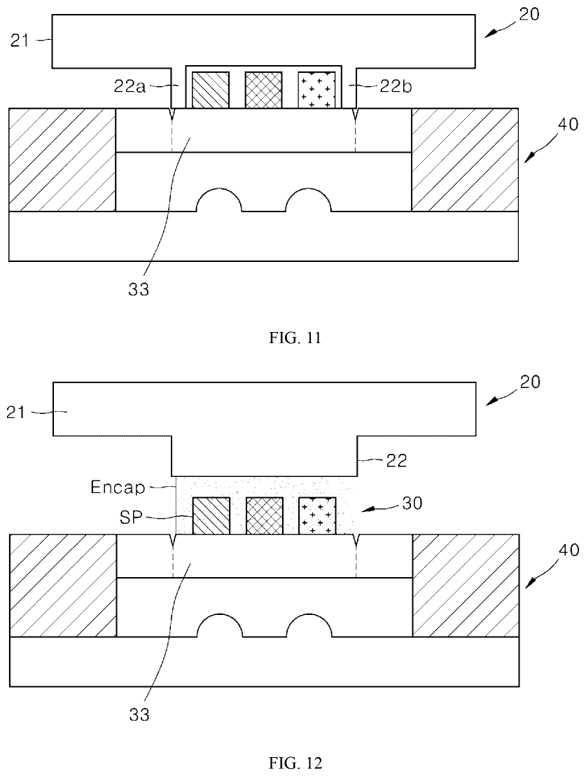

FIG. 11 is a view representing a configuration example of a transfer member according to one or more embodiments of the present disclosure. FIG. 12 is a view representing an example in which an encapsulation layer covering sub-elements is picked up by a transfer member according to one or more embodiments of the present disclosure.

Referring to FIG. 11, in a transfer member 20 according to one or more embodiments of the present disclosure, a stamp layer 22 may include a first pickup portion 22a and a second pickup portion 22b that protrude to a height greater than the height of each sub-element.

When the transfer member 20 comes into contact with the donor member 40, the first pickup portion 22a and the second pickup portion 22b of the stamp layer 22 may pick up a plurality of sub-elements disposed on the package lower substrate 33 while surrounding them.

When the transfer member 20 picks up the plurality of light-emitting elements from the donor member 40, the first pickup portion 22a and the second pickup portion 22b may be adhered or stuck to the tether of the donor member 40 so that the plurality of light-emitting elements are positioned between the first pickup portion 22a and the second pickup portion 22b.

The stamp layer 22 adheres to the package lower substrate 33 so that the bottom surfaces of the first pickup portion 22a and the second pickup portion 22b come into contact with the package lower substrate 33 while the first pickup portion 22a and the second pickup portion 22b surround the plurality of sub-elements.

Referring to FIG. 12, a transfer member 20 according to one or more embodiments of the present disclosure can be adhered by contacting a stamp layer 22 with an encapsulation layer Encap covering a plurality of sub-elements SP1 to SP3.

Therefore, when the transfer member 20 moves in an upward direction, the tensile force of the stamp layer 22 is transmitted to the package lower substrate 33 through the encapsulation layer Encap, and the package lower substrate 33 is broken off and separated from the donor member 40 by the tensile force.

The plurality of sub-elements SP1 to SP3 may be transferred onto the display panel in a state of being covered by the encapsulating layer Encap.

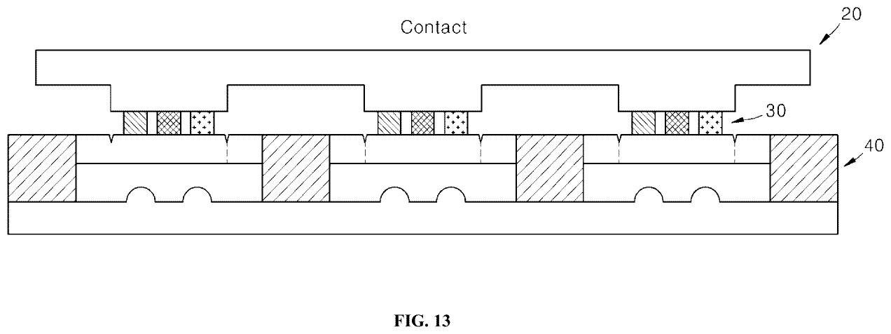

FIGS. 13 to 16 are views representing processes for picking up and transferring sub-elements from a donor member according to one or more embodiments of the present disclosure.

Referring to FIG. 13, a transfer member 20 according to one or more embodiments of the present disclosure may come into contact with a plurality of light-emitting element packages 30 to pick up the light-emitting element packages 30 from a donor member 40, each package including sub-elements.

In FIGS. 13 to 16, the reference symbols for the same components as those described above are omitted.

The transfer element 20 may have an adhesive material or a sticky material applied to the surface of the stamp layer 22, so that the stamp layer 22 and the sub-elements of each light-emitting element package 30 can be adhered to each other.

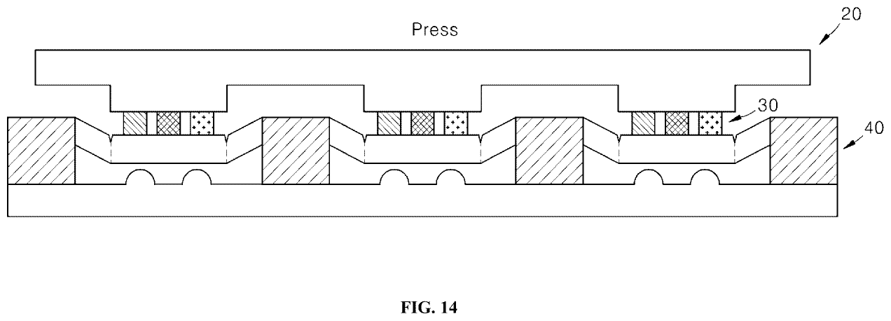

Referring to FIG. 14, the transfer member 20 may apply a pressure Press to the donor member 40 by the transport member 10.

Accordingly, the stamp layer 22 of the transfer member 20 can be adhered to the sub-elements of the light-emitting element package 30, and the tether 43 and the package lower substrate 33 connected to the tether 43 can be sagged downward by this pressure.

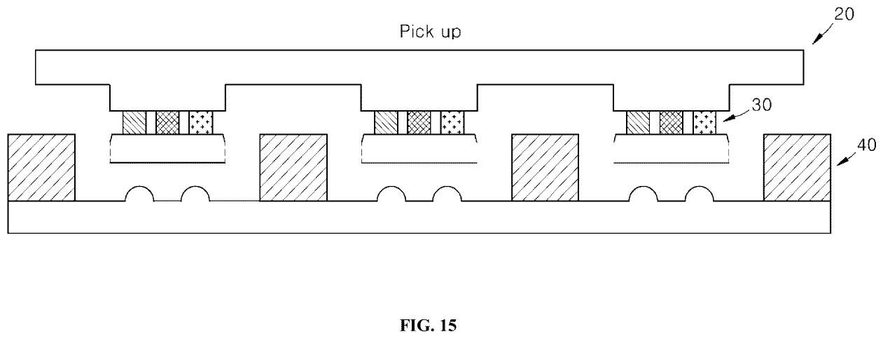

Referring to FIG. 15, the transfer member 20 according to one or more embodiments of the present disclosure moves upward by the tensile force of the transport member 10, and the plurality of sub-elements adhered to the stamp layer 22 and the package lower substrate 33 are broken off and separated from the donor member 40.

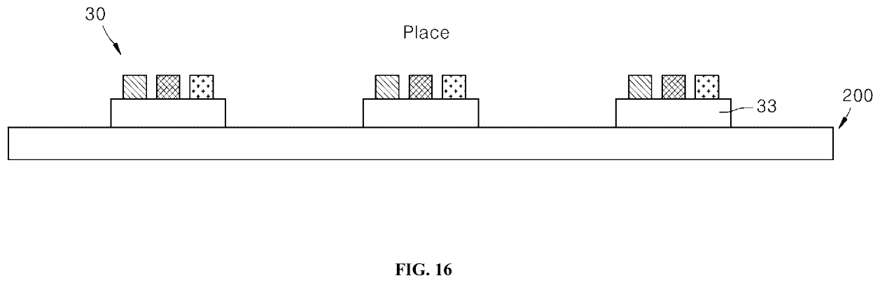

Referring to FIG. 16, the transfer member 20 according to one or more embodiments of the present disclosure may transfer the sub-elements of the light-emitting element packages 30 which have been picked up from the donor member 40, by placing them on the display panel 200.

In this regard, the transfer member 20 may bond the plurality of sub-elements onto a circuit board (not shown) of the display panel 200. On the circuit board a flux of a predetermined thickness may be applied. The flux may be a material that facilitates the bonding of the circuit board and the bonding electrodes during a press-melt process with the use of a laser. The flux may be oil-soluble or water-soluble, and contain natural or synthetic rosins. The flux may be in a liquid form or in a gel form. After the press-melt process is completed, the flux is removed.

A plurality of sub-elements, which are bonding objects, are disposed on the circuit board, with a bonding electrode disposed on a respective one surface of the sub-elements, which comes into contact with the circuit board.

The transfer member 20 is disposed on the other surface of the sub-elements, so that the sub-elements and the transfer member 20 overlap with each other. Additionally, the laser transmitting part (not shown) of the transport member 10 overlaps on the transfer member 20. Thereby, the bonding electrode, the light-emitting element LED, the transfer member 20, and the laser transmitting part overlap with each other in the bonding area (not shown).

As the heating member irradiates the laser to the bonding electrode in a state where the transport member 10 presses the transfer member 20, the laser can be irradiated to the bonding electrode, passing through the laser transmitting part and the transfer member 20.

Accordingly, the heating element can heat the bonding electrode to a melting temperature of the bonding electrode, thereby press-melt bonding the circuit board with the bonding electrode. Here, the press-melt bonding refers to a state in which the bonding electrode is heated and melted to melt-mix the light-emitting element 31 with an anode pad electrode and a cathode pad electrode, and then cooled and solidified after the cease of the laser supply. Since the conductivity by the anode pad electrode and the cathode pad electrode with the light-emitting element 31 is maintained as they are cooled and solidified from the melt-mixed state, the anode pad electrode and the cathode pad electrode can be respectively electrically and physically connected with the light-emitting element 31.

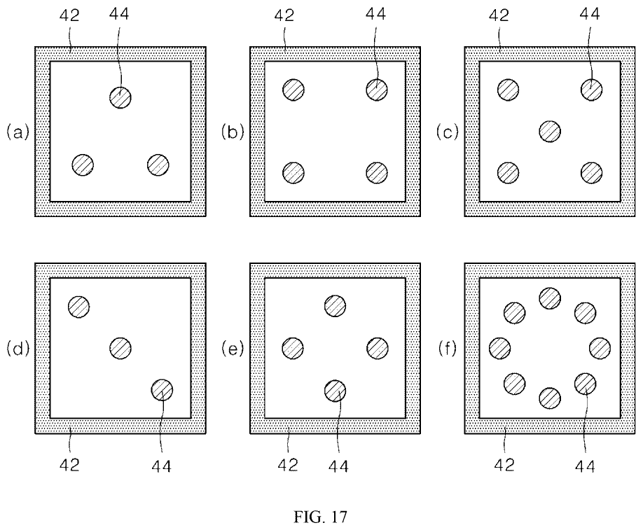

FIG. 17 is a plan view showing various embodiments of protrusions formed on a substrate in a donor member according to one or more embodiments of the present disclosure.

Referring to the embodiment (a) in FIG. 17, a donor member 40 according to one or more embodiments of the present disclosure may have three protrusions 44 corresponding to vertices, respectively, of a triangle on the bottom of the substrate inside the anchor 42 whose four sides form a rectangle. Here, the anchor 42 surrounds three protrusions 44 in four directions.

Alternatively, in the embodiment (b) in FIG. 17, the donor member 40 may have four protrusions 44 corresponding to vertices, respectively, of a rectangle on the bottom of the substrate inside the anchor 42 whose four sides form a rectangle.

Alternatively, in the embodiment (c) in FIG. 17, the donor member 40 may have five protrusions 44 corresponding to vertices and a center point, respectively, of a rectangle on the bottom of the substrate inside the anchor 42 whose four sides form a rectangle.

Alternatively, in the embodiment (d) in FIG. 17, the donor member 40 may have three protrusions 44 disposed at regular intervals along a diagonal direction from the upper left corner to the lower right corner on the bottom of the substrate inside the anchor 42 whose four sides form a rectangle.

Alternatively, in the embodiment (e) in FIG. 17, the donor member 40 may have four protrusions 44 corresponding to vertices, respectively, of a diamond shape on the bottom of the substrate inside the anchor 42 whose four sides form a rectangle.

Alternatively, in the embodiment (f) in FIG. 17, the donor member 40 may have eight protrusions 44 disposed in a circular shape on the bottom of the substrate inside the anchor 42 whose four sides form a rectangle.

However, the embodiments of the present disclosure are not limited to these, and a plurality of protrusions 44 may be disposed in various shapes on the substrate of the donor member 40.

As described above, according to one or more embodiments of the present disclosure, it is possible to realize a display panel manufacturing apparatus that prevents light-emitting elements from being damaged when detached from a donor member in a transfer process.

In addition, according to one or more embodiments of the present disclosure, it is possible to provide a display panel manufacturing apparatus which can prevent damage to a light-emitting element package without the occurrence of misalignment between a transfer member and light-emitting elements by enabling the light-emitting elements to be easily detached from a donor member without being damaged during a transfer process.

The display panel manufacturing apparatus according to various embodiments of the present disclosure may be described as follows.

A display panel manufacturing apparatus according to one or more embodiments of the present disclosure may include a donor member in which a plurality of light-emitting elements are disposed to be connected to each other by a tether structure; and a transfer member picking up the plurality of light-emitting elements from the donor member and transferring them onto a display panel, and the tether structure may include a plurality of anchors spaced apart at regular intervals on a substrate, and a plate-shaped tether disposed on the plurality of anchors, and each of the plurality of light-emitting elements may disposed on the tether between the plurality of anchors.

According to some embodiments of the present disclosure, a plurality of protrusions are formed on the substrate between the plurality of anchors.

According to some embodiments of the present disclosure, each of the plurality of protrusions may have one or more shapes among a hemisphere shape, a rectangular parallelepiped shape, a hexahedron shape, a cylinder shape, and a hemispherical columnar shape.

According to some embodiments of the present disclosure, each of the plurality of protrusions may have a height smaller than a height of the plurality of anchors.

According to some embodiments of the present disclosure, each of the plurality of protrusions may have a thickness smaller than a thickness of the plurality of anchors.

According to some embodiments of the present disclosure, the tether between the anchor and the light-emitting element may include a straight surface in a plate shape, a through-hole surface in which a through-hole is formed, and a trench surface in which a trench is formed.

According to some embodiments of the present disclosure, a width of the through-hole surface may be equal to a width of the light-emitting element, and be greater than a width of the straight surface.

According to some embodiments of the present disclosure, a width of the straight surface may be equal to a width of the trench surface.

According to some embodiments of the present disclosure, a width of each of the light-emitting elements may be equal to a width of each of the anchors and a width of the through-hole surface.

According to some embodiments of the present disclosure, wherein on an upper surface of the tether an adhesive material or a sticky material is applied, and the tether may be adhered or stuck to the plurality of light-emitting elements by the adhesive material or the sticky material.

According to some embodiments of the present disclosure, the transfer member may include a base layer and a stamp layer disposed on one surface of the base layer.

According to some embodiments of the present disclosure, on a surface of the stamp layer, an adhesive material or a sticky material may be applied.

According to some embodiments of the present disclosure, when the transfer member picks up the plurality of light-emitting elements from the donor member, the transfer member may be adhered or stuck to the plurality of light-emitting elements by the adhesive material or the sticky material of the stamp layer.

According to some embodiments of the present disclosure, a stickiness or adhesion between the transfer member and the plurality of light-emitting elements may be greater than a stickiness or adhesion between the donor member and the plurality of light-emitting elements.

According to some embodiments of the present disclosure, when the transfer member picks up the plurality of light-emitting elements from the donor member, the tether between the plurality of anchors and the plurality of light-emitting elements may be broken.

According to some embodiments of the present disclosure, each of the light-emitting elements may include one or more sub-elements among a sub-element of a first color, a sub-element of a second color, a sub-element of a third color, and a sub-element of a fourth color, the one or more sub-elements being adhered or stuck to the tether by an adhesive material or a sticky material on the tether.

According to some embodiments of the present disclosure, the one or more sub-elements may be disposed on a package lower substrate, and the stamp layer may include a first pickup portion and a second pickup portion which protrude to a height greater than a height of each of the sub-elements.

According to some embodiments of the present disclosure, when the transfer member picks up the plurality of light-emitting elements from the donor member, the first pickup portion and the second pickup portion may be adhered or stuck to the tether so that the plurality of light-emitting elements are positioned between the first pickup portion and the second pickup portion.

According to some embodiments of the present disclosure, the light-emitting element may include a micro LED.

Although the present disclosure has been described with reference to the drawings provided as examples, the present disclosure is not limited to the drawings and embodiments disclosed in this disclosure, and it is obvious that various modifications can be made by those skilled in the art without departing from the scope of the technical idea of the present invention. In addition, even if operational effects according to the configuration of the present disclosure were not explicitly described while explaining the embodiments of the present disclosure, it is natural that the effects that can be predicted by that configuration should also be acknowledged.

What is claimed is:

1. A display panel manufacturing apparatus, comprising:
a donor member, wherein a plurality of light-emitting elements are disposed on the donor member by a tether structure and connected to each other by the tether structure; and
a transfer member configured to pick up the plurality of light-emitting elements from the donor member and transfer the plurality of light-emitting elements onto a display panel,
wherein the tether structure includes a plurality of anchors spaced apart at regular intervals on a substrate of the donor member, and a plate-shaped tether disposed on the plurality of anchors, and
wherein each of the plurality of light-emitting elements is disposed on a tether between the plurality of anchors.

2. The display panel manufacturing apparatus of claim 1, wherein a plurality of protrusions are formed on the substrate between the plurality of anchors.

3. The display panel manufacturing apparatus of claim 2, wherein each of the plurality of protrusions has one or more shapes among a hemisphere shape, a rectangular parallelepiped shape, a hexahedron shape, a cylinder shape, and a hemispherical columnar shape.

4. The display panel manufacturing apparatus of claim 2, wherein each of the plurality of protrusions has a height smaller than a height of the plurality of anchors.

5. The display panel manufacturing apparatus of claim 2, wherein each of the plurality of protrusions has a thickness smaller than a thickness of the plurality of anchors.

6. The display panel manufacturing apparatus of claim 1, wherein the tether between the anchor and the light-emitting element includes a straight surface in a plate shape, a through-hole surface in which a through-hole is formed, and a trench surface in which a trench is formed.

7. The display panel manufacturing apparatus of claim 6, wherein a width of the through-hole surface is equal to a width of the light-emitting element, and wherein the width of the through-hole surface is greater than a width of the straight surface.

8. The display panel manufacturing apparatus of claim 6, wherein a width of the straight surface is a same as a width of the trench surface.

9. The display panel manufacturing apparatus of claim 6, wherein a width of each of the plurality of light-emitting elements is equal to a width of each of the plurality of anchors and a width of the through-hole surface.

10. The display panel manufacturing apparatus of claim 1, wherein an adhesive material or a sticky material is applied on an upper surface of the tether, and
wherein the tether is adhered or stuck to the plurality of light-emitting elements by the adhesive material or the sticky material.

11. The display panel manufacturing apparatus of claim 1, further comprising a bonding electrode disposed on a surface of the plurality of light-emitting elements towards the donor member.

12. The display panel manufacturing apparatus of claim 1, wherein the transfer member includes a base layer and a stamp layer disposed on one surface of the base layer.

13. The display panel manufacturing apparatus of claim 12, wherein an adhesive material or a sticky material is applied on a surface of the stamp layer.

14. The display panel manufacturing apparatus of claim 13, wherein, when the transfer member picks up the plurality of light-emitting elements from the donor member, the transfer member is adhered or stuck to the plurality of light-emitting elements by the adhesive material or the sticky material of the stamp layer.

15. The display panel manufacturing apparatus of claim 14, wherein a stickiness or an adhesion between the transfer member and the plurality of light-emitting elements is greater than a stickiness or an adhesion between the donor member and the plurality of light-emitting elements.

16. The display panel manufacturing apparatus of claim 15, wherein, when the transfer member picks up the plurality of light-emitting elements from the donor member, the tether between the plurality of anchors and the plurality of light-emitting elements is broken.

17. The display panel manufacturing apparatus of claim 12, wherein each of the plurality of light-emitting elements includes one or more sub-elements among a sub-element of a first color, a sub-element of a second color, a sub-element of a third color, and a sub-element of a fourth color, the one or more sub-elements being adhered or stuck to the tether by an adhesive material or a sticky material on the tether.

18. The display panel manufacturing apparatus of claim 17, wherein the one or more sub-elements are disposed on a package lower substrate, and
wherein the stamp layer includes a first pickup portion and a second pickup portion, the first pickup portion and the second pickup portion protruding to a height greater than a height of each of the one or more sub-elements.

19. The display panel manufacturing apparatus of claim 18, wherein, when the transfer member picks up the plurality of light-emitting elements from the donor member, the first pickup portion and the second pickup portion are adhered or stuck to the tether so that the plurality of light-emitting elements are positioned between the first pickup portion and the second pickup portion.

20. The display panel manufacturing apparatus of claim 1, wherein the light-emitting element includes a micro light-emitting diode (LED).
